(19) United States
(12) Patent Application Publication
(10) Pub. No.: US 2010/0283622 A1
(43) Pub. Date: Nov. 11, 2010

(54) KEYBOARD MODULE AND ELECTRONIC DEVICE USING THE SAME

(75) Inventors: Yong-Feng Gu, Shanghai City (CN); Jacky Hung, Shanghai City (CN)

Correspondence Address: J C PATENTS, 4 VENTURE, SUITE 250, IRVINE, CA, 92618, US

(73) Assignee: INVENTEC APPLIANCES CORP., Taipei (TW)

(21) Appl. No.: 12/774,121

(22) Filed: May 5, 2010

(30) Foreign Application Priority Data
May 6, 2009 (TW) 98207757

(51) Int. Cl. G08B 21/00; H03K 17/94

(52) U.S. Cl. 340/652; 341/22

(57) ABSTRACT

A keyboard module adapted for connecting with a security unit is provided. The keyboard module includes a bottom plate, a plurality of buttons and a flexible circuit board. The buttons are disposed on the bottom plate, and the flexible circuit board is disposed between the bottom plate and the buttons. The flexible circuit board has a wire mesh circuit. The wire mesh circuit is adapted for electrically connecting with the security unit, so that the security unit generates a trigger signal while the wire mesh circuit is broken.

### CROSS-REFERENCE TO RELATED APPLICATION

This application claims the priority benefit of Taiwan application serial no. 98207757, filed on May 6, 2009. The entirety of the above-mentioned patent application is hereby incorporated by reference herein and made a part of specification.

### BACKGROUND OF THE INVENTION

1. Field of the Invention

The present invention relates to a keyboard module. More particularly, the present invention relates to a keyboard module having a security protection function.

2. Description of Related Art

Generally, a point of sales (POS) system uses a computer to perform goods entry and gather statistics of goods information, so as to provide a correct and quick goods sales information (such as, quantity, amount, gross margin, inventory, etc. of the goods). Moreover, the POS system generally has a network connection and has a credit card reading function, and can further record product-ordering information of consumers. In addition, the POS system is generally used in convenience stores, restaurants and hotels, etc. for entry of goods, menus and rooms.

In other words, a function of the POS system gradually trends to be diversified. By suitably matching a hardware module with a software module of the POS system, the POS system can perform synchronous operation and statistics to information such as book and stationery management, catering sales, tickets, cash statistics or logistics system, etc.

A conventional hardware module of the POS system includes a computer host, an input device and peripheral components. The peripheral components generally include a cashier display, a customer display, a card reader, a swipe card reader, a scanner, a printer and a cash box, etc. Moreover, the input device can also be referred to as a data entry device, which is, for example, a keyboard module, by which a cashier can input names and amount of goods purchased by a consumer.

However, since the languages used in various countries can be different, the POS system may require different keyboard layout designs to cope with different characters, so as to facilitate the users of different countries. Moreover, based on a security consideration, the keyboard module of the POS system is generally designed to be irreplaceable after assembly thereof is completed. Therefore, it is necessary and practical to design a replaceable keyboard module having a security protection function for the POS system.

### SUMMARY OF THE INVENTION

The present invention is directed to a keyboard module, which has a security protection function.

The present invention is directed to an electronic device, which has a relatively high security.

The present invention provides a keyboard module suitable for connecting with a security unit used to activate a protection mechanism. The keyboard module includes a bottom plate, a plurality of buttons and a flexible circuit board. The buttons are disposed on the bottom plate, and the flexible circuit board is disposed between the bottom plate and the buttons. The flexible circuit board has a wire mesh circuit. The wire mesh circuit is suitable for electrically connecting with the security unit, wherein when the wire mesh circuit is broken, the security unit generates a trigger signal to activate the protection mechanism.

In an embodiment of the present invention, the wire mesh circuit is fixed to the buttons, wherein when at least one of the buttons is removed from the wire mesh circuit, the wire mesh circuit is broken.

In an embodiment of the present invention, an area measurement of the wire mesh circuit is substantially corresponds to an area measurement of the buttons.

In an embodiment of the present invention, each of the buttons has a keycap and a connector, and the connector is connected between the keycap and the bottom plate.

The present invention provides an electronic device including an input device and a security unit. The input device includes a bottom plate, a plurality of buttons and a flexible circuit board. The buttons are disposed on the bottom plate, and the flexible circuit board is disposed between the bottom plate and the buttons. The flexible circuit board has a metal circuit. The security unit is electrically connected to the metal circuit, so as to generate a trigger signal used to activate a protection mechanism when the metal circuit is broken.

In an embodiment of the present invention, the metal circuit has a mesh.

In an embodiment of the present invention, the metal circuit is fixed to the buttons, wherein when at least one of the buttons is removed from the metal circuit, the metal circuit is broken.

In an embodiment of the present invention, an area measurement of the metal circuit is substantially corresponds to an area measurement of the buttons.

In an embodiment of the present invention, each of the buttons has a keycap and a connector, and the connector is connected between the keycap and the bottom plate.

In an embodiment of the present invention, the electronic device further includes a backup battery, which is electrically connected to the security unit for providing power for the security unit.

In an embodiment of the present invention, the electronic device further includes an alarm. The alarm is electrically connected to the security unit for receiving the trigger signal and generating a warning signal.

In an embodiment of the present invention, the alarm includes a buzzer or a warning lamp.

In an embodiment of the present invention, the electronic device further includes an electric zebra connector, and the electric zebra connector is electrically connected to the security unit and the metal circuit. The security unit determines whether the metal circuit is broken through the electric zebra connector.

According to the above descriptions, in the electronic device of the present invention, when the metal circuit is broken, the security unit can generate a trigger signal to activate a function of protecting internal data of the electronic device, and therefore the internal data of the electronic device can be protected from stealing or spoiling.

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram illustrating an electronic device according to an embodiment of the present invention.

FIG. 2 is an exploded view of a part of components of an electronic device according to an embodiment of the present invention.

FIG. 3 is a schematic diagram illustrating a metal circuit according to an embodiment of the present invention.

### DESCRIPTION OF THE EMBODIMENTS

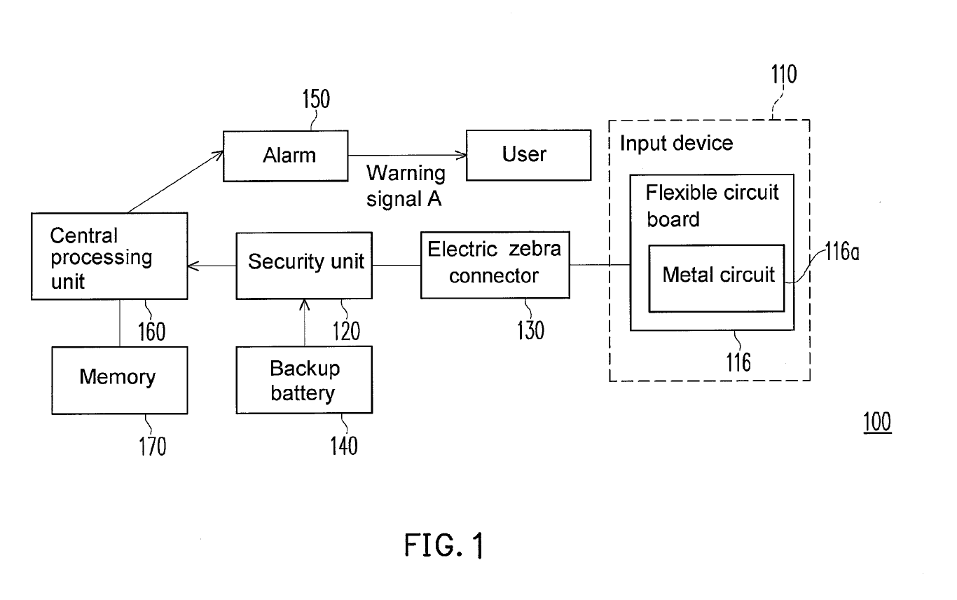

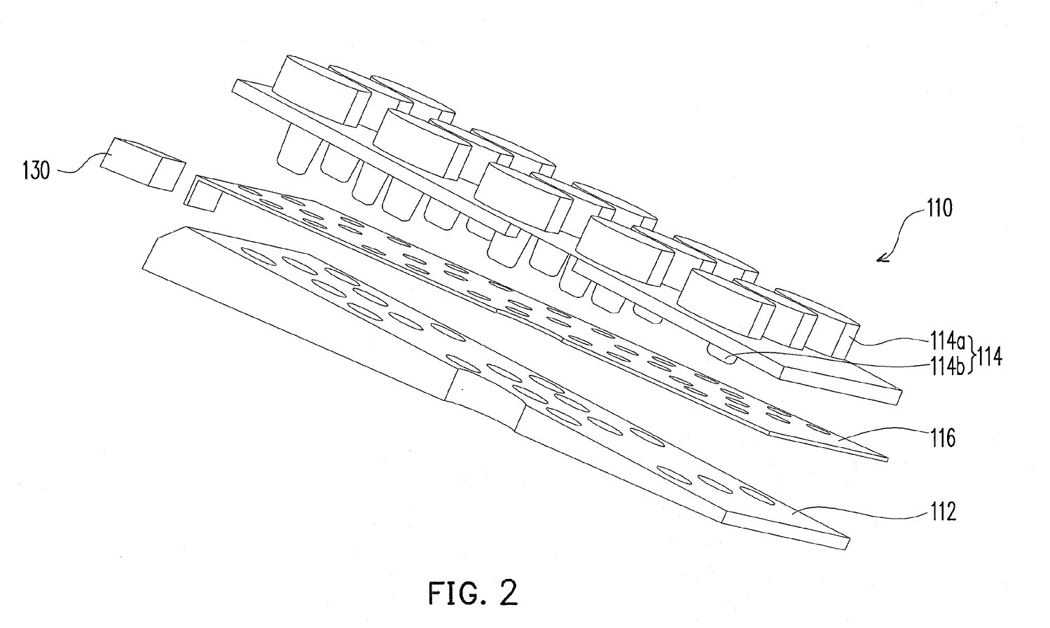

FIG. 1 is a block diagram illustrating an electronic device according to an embodiment of the present invention, and FIG. 2 is an exploded view of a part of components of the electronic device according to an embodiment of the present invention. Referring to FIG. 1 and FIG. 2, the electronic device 100 mainly includes an input device 110 and a security unit 120, wherein the input device 110 is electrically connected to the security unit 120. In the present embodiment, the input device 110 includes a bottom plate 112, a plurality of buttons 114 and a flexible circuit board 116. Moreover, the electronic device 100 can be used in a point of sales (POS) system (not shown) for providing a relatively high security for the POS system. Moreover, the input device 100 is, for example, a keyboard module. A user can perform data entry through the input device 110.

The buttons 114 are disposed on the bottom plate 112, and the flexible circuit board 116 is disposed between the bottom plate 112 and the buttons 114. Moreover, the flexible circuit board 116 has a metal circuit 116a, and the metal circuit 116a is electrically connected to the security unit 120. It should be noticed that when the security unit 120 detects that the metal circuit 116a is a broken circuit, the security unit 120 generates a trigger signal to activate a protection or a warning mechanism, so as to protect internal data or a system program of the electronic device 100 from stealing or spoiling.

In detail, in the present embodiment, the metal circuit 116a covers the flexible circuit board 116, and is fixed to bottoms of the buttons 114. Moreover, an area measurement of the metal circuit 116a is substantially conformed to an area measurement of the buttons 114. Therefore, if the input device 110 is drilled, the metal circuit 116a can be damaged and broken, so that an integral circuit thereof cannot be achieved. When the security unit 120 detects that the metal circuit 116a is broken, the security unit 120 generates the trigger signal to protect the internal data of the electronic device 100.

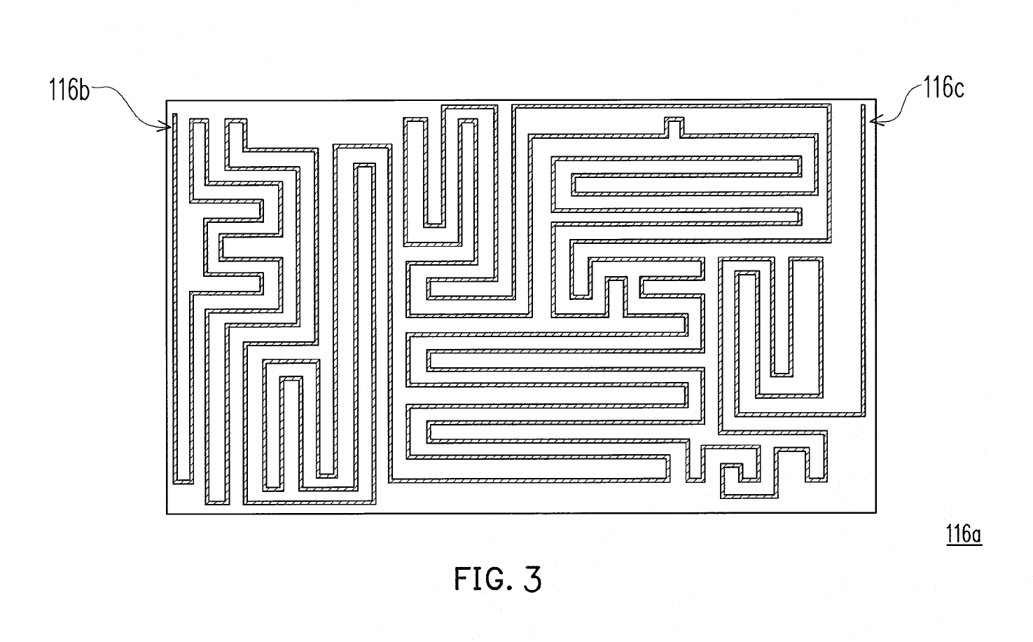

FIG. 3 is a schematic diagram illustrating a metal circuit according to an embodiment of the present invention. Referring to FIG. 1, FIG. 2 and FIG. 3, in the present embodiment, the metal circuit 116a has a mesh distribution, and two terminals 116b and 116c of the metal circuit 116a are all connected to the security unit 120. The security unit 120 can continuously transmit test signals to the metal circuit 116a through one terminal 116b, and receives the test signals from the other terminal 116c. If the security unit 120 can receive a reply of the test signal from the terminal 116c, it can be determined that the metal circuit 116a is a closed circuit. Comparatively, if the security unit 120 cannot receive the replay of the test signal from the terminal 116c, it can be determined that the metal circuit 116a is a broken circuit.

For example, in the present embodiment, the metal circuit 116a is normally a closed circuit, and the bottoms of the buttons 114 are directly stuck on the metal circuit 116a. Therefore, when one of the buttons 114 is removed from the bottom plate 112, a part of the metal circuit 116a stuck to the button 114 is peeled off and damaged, so that the metal circuit 116a is broken. In the mean time, since the security unit 120 cannot receive the replay of the test signal, the security unit 120 generates the trigger signal to activate the protection mechanism or the warning mechanism. Moreover, in another embodiment that is not illustrated, the metal circuit 116a can be designed as a plurality of disconnected segment lines, and the segment lines are connected through the buttons 114 to form an integral closed circuit. Therefore, if any of the buttons 114 is removed from the bottom plate 112, the removed button 114 cannot conduct the metal circuit 116a. Now, the metal circuit 116a is also broken, so that the security unit 120 can generate the trigger signal.

In the present embodiment, the electronic device 100 further includes an electric zebra connector 130. Moreover, the electric zebra connector 130, for example, directly contacts a pad (not shown) of the flexible circuit board 116, so that the electric zebra connector 130 is electrically connected to the security unit 120 and the metal circuit 116a. Therefore, the security unit can determine whether the metal circuit 116a is broken through the electric zebra connector 130. Moreover, if the electric zebra connector 130 is damaged or removed, the metal circuit 116a cannot transmit the test signal back to the security unit 120 through the electric zebra connector 130. Now, the security unit 120 also generates the trigger signal to warn the user. Namely, even if the input device 110 is integrally removed without being damaged, the electric zebra connector 130 can be immediately broken, so that the security unit 120 can generate the trigger signal.

Moreover, in the present embodiment, the electronic device 100 has a main power source (not shown) and a backup battery 140. Even some one intends to cut off the main power source of the electronic device 100 to stop the security unit 120 generating the trigger signal, the security unit 120 can still work based on the power provided by the backup battery 140. In other words, when the metal circuit 116a is broken, the backup power 140 can provide the power required by the security unit 120, so as to maintain a security of the electronic device 100.

Moreover, in the present invention, the electronic device 100 further includes a memory 170 for storing the internal data or the system program. The memory is electrically connected to a central processing unit (CPU) 160. To closely protect the internal data or the system program of the electronic device 100, when the security unit 120 determines that the metal circuit 116a is broken, the CPU 160 can delete the internal data or lock the system program through the memory 170, so as to prevent others from copying and reading the internal data or rewriting the system program. Therefore, the electronic device 100 of the present embodiment has a high security. The backup battery 140 also provides the power required by the memory 170 when the main power source is cut off, so that the memory 170 can still work when the main power source is cut off.

It should be noticed that after the internal data or the system program is deleted or locked, the user can notify an original supplier to rewrite or unlock the data of the memory, so as to enable a normal operation of the hardware.

Moreover, to achieve a better warning effect, the electronic device 100 can include an alarm 150, and the alarm 150 is electrically connected to the security unit 120. In detail, when the metal circuit 116a is broken, the security unit 120 can transmit the trigger signal to the CPU 160 of the electronic device 100. The CPU 160 receives the trigger signal and transmits it to the alarm 150. Then, the alarm 150 receives the trigger signal and generates a warning signal A to the user.

In detail, in the present embodiment, the alarm 150 can include a buzzer or a warning lamp. The buzzer can send sounds of “beep, beep” or other single tones to provide the warning function. The warning lamp is, for example, a light emitting diode (LED), a lamp or other suitable light sources. Therefore, when the CPU 160 receives the trigger signal, the CPU 160 can activate the buzzer or the warning lamp, so that the buzzer or the warning lamp can generate the warning signal A.

In other words, when the security unit 120 determines that, the buzzer can send sound to provide an audio warning signal A. Alternatively, the warning lamp can emit light to provide a video warning signal A. Therefore, the electronic device 100 has a relatively high security. Moreover, in another embodiment that is not illustrated, the metal circuit 116a is broken or not may be determine another determining unit. When the determining unit determine the metal circuit 116a is broken, the determining unit informs the security unit 120 to generate the trigger signal.

It should be noticed that the alarm 150 can include only one of the warning lamp and the buzzer to achieve the warning effect. Therefore, regarding actual demands of different POS systems, the alarm 150 can include both of the warning lamp and the buzzer or can include only one of the warning lamp and the buzzer. As long as the alarm can achieve the warning effect, it is considered to be within the scope of the present invention, and a type of the alarm is not limited by the present invention.

Moreover, in another embodiment that is not illustrated, the input device 100 can further include a thin-film circuit board. The thin-film circuit board is disposed between the bottom plate 112 and the flexible circuit board 116. In addition, the thin-film circuit board may have a plurality of press portions, and the buttons 114 are respectively deployed corresponding to the press portions. Therefore, when the user presses the button 114, the button 114 contacts the corresponding press portion, so that an input instruction can be transmitted to the electronic device 100 through the thin-film circuit board.

For example, each of the buttons 114 may have a keycap 114a and a connector 114b, wherein the connector 114b is connected between the keycap 114a and the bottom plate 112. The user can vertically press down the keycap 114a to drive the connector 114b contacting the press portion of the thin-film circuit board, so as to transmit the input instruction to the electronic device 100 through the thin-film circuit board. Moreover, the connector 114b is, for example, a scissor-type linkage mechanism, and when the user stop pressing the button 114, the scissor-type linkage mechanism can drive the button 114 to quickly return back to its original position, so as to facilitate the user continually inputting data.

Moreover, the thin-film circuit board can be a thin-film switch, which is, for example, formed by an upper conductive layer, a lower conductive layer and an insulating layer disposed between the upper and the lower conductive layers. When the user presses the button 114 to drive the button 114 contacting the press portion, the upper conductive layer contacts the lower conductive layer through a via, so as to conduct the thin-film switch. Therefore, the input instruction can be transmitted to the electronic device through the thin-film circuit board. Moreover, the thin-film circuit board can also be a capacitive sensing switch or other suitable switches, which is determined according to actual demands, and is not limited by the present invention.

In summary, in the electronic device of the present invention, when the metal circuit is broken, the security unit can generate a trigger signal to activate a protection mechanism, so as to protect the internal data of the electronic device from stealing or spoiling. Moreover, the security unit can determine whether the metal circuit is broken through an electric zebra connector. When the electric zebra connector is damaged, the input device is drilled, or any button is removed from the bottom plate, the metal circuit is broken, so that the security unit can generate the trigger signal. In addition, when the metal circuit is broken, the backup battery can provide power required by the security unit. Further, the electronic device also includes an alarm, and the alarm can generate an audio/video warning signal to achieve a better warning effect.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A keyboard module, suitable for connecting with a security unit used to activate a protection mechanism, the keyboard module comprising:
a bottom plate;
a plurality of buttons, disposed on the bottom plate; and
a flexible circuit board, disposed between the bottom plate and the buttons, and having a wire mesh circuit suitable for electrically connecting with the security unit, wherein when the wire mesh circuit is broken, the security unit generates a trigger signal to activate the protection mechanism.

2. The keyboard module as claimed in claim 1, wherein the wire mesh circuit is fixed to the buttons, wherein when at least one of the buttons is removed from the wire mesh circuit, the wire mesh circuit is broken.

3. The keyboard module as claimed in claim 1, wherein an area measurement of the wire mesh circuit substantially corresponds to an area measurement of the buttons.

4. The keyboard module as claimed in claim 1, wherein each of the buttons has a keycap and a connector, and the connector is connected between the keycap and the bottom plate.

5. An electronic device, comprising:
an input device, comprising:
a bottom plate;
a plurality of buttons, disposed on the bottom plate; and
a flexible circuit board, disposed between the bottom plate and the buttons, and having a metal circuit; and
a security unit for electrically connecting to the metal circuit, and for generating a trigger signal used to activate a protection mechanism when the metal circuit is broken.

6. The electronic device as claimed in claim 5, wherein the metal circuit comprises a mesh.

7. The electronic device as claimed in claim 5, wherein the metal circuit is fixed to the buttons, wherein when at least one of the buttons is removed from the metal circuit, the metal circuit is broken.

8. The electronic device as claimed in claim 5, wherein an area measurement of the metal circuit substantially corresponds to an area measurement of the buttons.

9. The electronic device as claimed in claim 5, wherein each of the buttons has a keycap and a connector, and the connector is connected between the keycap and the bottom plate.

10. The electronic device as claimed in claim 5, further comprising a backup battery electrically connected to the security unit for providing power for the security unit.

11. The electronic device as claimed in claim 5, further comprising an alarm electrically connected to the security unit for receiving the trigger signal and generating a warning signal.

12. The electronic device as claimed in claim 11, wherein the alarm includes a buzzer or a warning lamp.

13. The electronic device as claimed in claim 5, further comprising an electric zebra connector electrically connected to the security unit and the metal circuit, wherein the security unit determines whether the metal circuit is broken through the electric zebra connector.
